(19) United States
(12) Patent Application Publication
(10) Pub. No.: US 2016/0148813 A1
(43) Pub. Date: May 26, 2016

(54) GAS INJECTION METHOD FOR UNIFORMLY PROCESSING A SEMICONDUCTOR SUBSTRATE IN A SEMICONDUCTOR SUBSTRATE PROCESSING APPARATUS

(71) Applicant: Lam Research Corporation, Fremont, CA (US)

(72) Inventors: James Rogers, Los Gatos, CA (US); Zhigang Chen, Campbell, CA (US); John Holland, San Jose, CA (US); Kyle Spaulding, San Jose, CA (US)

(73) Assignee: Lam Research Corporation

(21) Appl. No.: 14/553,439

(22) Filed: Nov. 25, 2014

(51) Int. Cl. H01L 21/3065; H01L 21/67

(52) U.S. Cl. CPC H01L 21/3065; H01L 21/67069

(57) ABSTRACT

A method of uniformly processing an upper surface of a semiconductor substrate in a plasma processing apparatus including a showerhead including gas outlets in discrete sectors of a process exposed surface thereof comprises processing the upper surface of the semiconductor substrate by flowing gas through a first discrete sector of the showerhead while preventing gas from flowing through an adjacent discrete sector of the showerhead, and processing the upper surface of the semiconductor substrate by flowing gas through a second discrete sector of the showerhead while preventing gas from flowing through an adjacent discrete sector of the showerhead. The flow of gas through the first discrete sector and the second discrete sector of the showerhead is time averaged such that the upper surface of the semiconductor substrate is uniformly processed.

### FIELD OF THE INVENTION

Embodiments disclosed herein pertain to methods of injecting gas through discrete sectors of a showerhead for uniformly processing a semiconductor substrate in a vacuum chamber of a semiconductor substrate processing apparatus, and may find particular use in methods of sequentially injecting gas through discrete sectors of a showerhead for uniformly processing a semiconductor substrate in a vacuum chamber of a semiconductor substrate processing apparatus.

### BACKGROUND

Semiconductor structures are processed in semiconductor substrate processing apparatuses such as a plasma processing apparatus that includes a vacuum chamber, a gas source that supplies process gas into the chamber, and an energy source that produces plasma from the process gas. Semiconductor structures are processed in such apparatuses by techniques including dry etching processes, wet etching processes, deposition processes, such as chemical vapor deposition (CVD), physical vapor deposition, or plasma-enhanced chemical vapor deposition (PECVD) of metal, dielectric and semiconductor materials and resist stripping processes. Different process gases are used for these processing techniques, as well as processing different materials of semiconductor structures.

### SUMMARY

Disclosed herein is a method of uniformly processing an upper surface of a semiconductor substrate in a semiconductor substrate processing apparatus. The semiconductor substrate processing apparatus includes a showerhead having gas outlets in discrete sectors of a process exposed surface thereof. The method comprises processing the upper surface of the semiconductor substrate by flowing gas through a first discrete sector of the showerhead while preventing gas from flowing through an adjacent discrete sector of the showerhead, and processing the upper surface of the semiconductor substrate by flowing gas through a second discrete sector of the showerhead while preventing gas from flowing through an adjacent discrete sector of the showerhead. The flow of gas through the first discrete sector and the second discrete sector of the showerhead is time averaged such that the upper surface of the semiconductor substrate is uniformly processed.

Also disclosed herein is a method of uniformly processing an upper surface of a semiconductor substrate in a semiconductor substrate processing apparatus. The semiconductor substrate processing apparatus includes a showerhead having gas outlets in discrete sectors of a process exposed surface thereof. The method comprises sequentially flowing gas through one or more of the discrete sectors while preventing the flow of gas through at least one other discrete sector wherein the gas flowed through the discrete sectors is time averaged such that the upper surface of the semiconductor substrate is uniformly processed.

### BRIEF DESCRIPTION OF THE DRAWING FIGURES

FIG. 1 is a schematic view of a plasma processing apparatus that may be used in accordance with embodiments disclosed herein.

FIGS. 2A-2C show process steps of sequential gas injection through discrete sectors of a showerhead according to embodiments disclosed herein.

### DETAILED DESCRIPTION

In the following detailed description, numerous specific embodiments are set forth in order to provide a thorough understanding of the systems, apparatuses, and methods disclosed herein. However, as will be apparent to those skilled in the art, that the present embodiments may be practiced without these specific details or by using alternate elements or processes. In other instances, well-known processes, procedures, and/or components have not been described in detail so as not to unnecessarily obscure aspects of embodiments disclosed herein. Like numerals in the figures indicate like elements. As used herein the term “about” refers to ±10%.

One metric for semiconductor substrate processing apparatuses is increased processing uniformity, which includes uniformity of process results on a semiconductor substrate surface as well as uniformity of process results of a succession of substrates processed with nominally the same input parameters. Continuous improvement of on-substrate uniformity is desirable. Among other things, this calls for plasma chambers with improved uniformity, consistency and self-diagnostics.

Non-uniform semiconductor substrate processing can be driven by spatial variation of RF power (e.g., plasma density in a vacuum chamber of a plasma processing apparatus), temperature (e.g., the temperature across an upper surface of a semiconductor substrate being processed or surrounding chamber parts), and/or chemical species (including activated and non-activated molecules and byproducts from chemical reactions and chemical nonuniformity). Embodiments of methods disclosed herein improve chemical uniformity during processing of semiconductor substrates such that semiconductor substrates are more uniformly processed (e.g., plasma etched). In a preferred embodiment, to improve chemical uniformity, gas can be injected into a vacuum chamber of a semiconductor substrate processing apparatus through a showerhead disposed above a semiconductor substrate wherein the showerhead can include a uniform hole pattern to thereby uniformly inject gas over the upper surface of a semiconductor substrate.

From symmetrical gas injection through a showerhead, the gas injected through the center of the showerhead toward the center of a semiconductor substrate has a longer residence time than gas injected radially outward from the center of the showerhead. The longer residence time occurs because gas must move radially outward from the center of the semiconductor substrate across the upper surface of the semiconductor substrate wherein the gas is removed from the vacuum chamber by a vacuum pump. Because the gas needs to flow to the edge of the semiconductor substrate to thereby be removed from the vacuum chamber, there is also a higher fraction of byproducts at the edge of the semiconductor substrate than at portions of the semiconductor substrate radially inward of the edge thereof. The flow path of gas supplied into a vacuum chamber during processing of the semiconductor substrate can result in the formation of a “W” shape in the critical dimensions (CD) of a processed semiconductor substrate wherein a peak is formed at the center of the processed semiconductor substrate, a low region is formed at the mid radius of the processed semiconductor substrate, and high region is formed at the edge of the processed semiconductor substrate.

Chemical non-uniformity can be reduced by injecting gas through different outlets disposed in discrete sectors formed in a process exposed surface (e.g., a plasma exposed surface) of a showerhead and sequencing the injection of gas through the discrete sectors of the showerhead in time. Thus, different areas across the upper surface of a semiconductor substrate being processed have similar or equal time average residence times (or gas flow) thereacross, and therefore better time averaged chemical uniformity. Preferably the discrete sectors are arranged around the center of the showerhead.

The semiconductor substrate processing apparatus can be a plasma processing apparatus such as a low-density, medium-density or high-density plasma reactor including an energy source that uses RF energy, microwave energy, magnetic fields, or the like to produce plasma. For example, the high-density plasma can be produced in a transformer coupled plasma (TCP™) reactor, also known as an inductively coupled plasma chamber, an electron-cyclotron resonance (ECR) plasma reactor, a capacitive-type discharge reactor, a capacitively coupled plasma processing chamber or the like. Exemplary plasma reactors that embodiments of the gas supply delivery arrangement can be used with include Exelan™ plasma reactors, such as the 2300 Excelan™ plasma reactor, available from Lam Research Corporation, located in Fremont, Calif. In an embodiment, a plasma processing system as disclosed herein can include a vacuum chamber which is an inductively coupled plasma processing chamber in which the gas injection system is a gas distribution plate, or alternatively, the chamber is a capacitively coupled plasma processing chamber in which the gas injection system may be a showerhead electrode. As used herein, the term “showerhead” may refer to a showerhead electrode or a gas distribution plate. During plasma etching processes, multiple frequencies can be applied to a substrate support incorporating an electrode and an electrostatic chuck. Alternatively, in dual-frequency plasma reactors, different frequencies can be applied to the substrate support and an electrode, such as a showerhead electrode, spaced from the semiconductor substrate so as to define a plasma generation region.

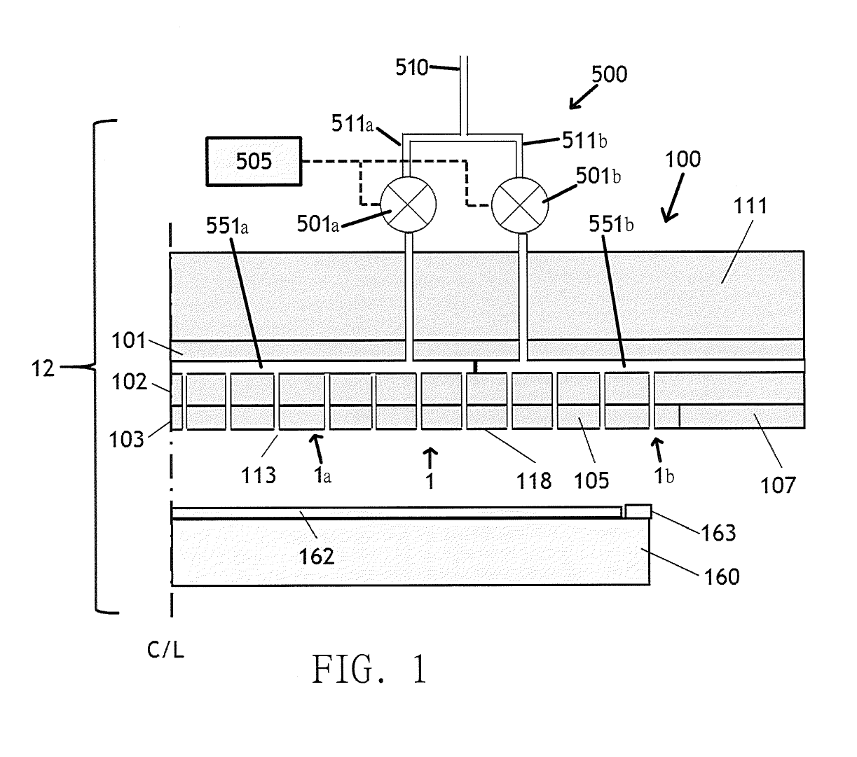

For example, FIG. 1 depicts one-half of a showerhead electrode assembly 100 of a parallel plate capacitively-coupled plasma processing apparatus operable to perform embodiments of methods disclosed herein. The showerhead electrode assembly 100 includes a showerhead electrode 103 and an optional backing member 102 secured to the showerhead electrode 103, a thermal control plate 101, and a top plate 111 which forms an upper wall of a vacuum chamber 12. The showerhead electrode 103 of the showerhead electrode assembly 100 is positioned above a substrate support 160 which is disposed in the vacuum chamber 12. The substrate support 160 includes an electrostatic clamping electrode (not shown) embedded therein such that the substrate support 160 is operable to support and electrostatically clamp a semiconductor substrate 162 (e.g., semiconductor wafer) on an upper surface thereof. An edge ring 163 may be fitted around the semiconductor substrate 162 to enhance etch uniformity during processing of the semiconductor substrate 162. The upper surface of the substrate support 160 can include grooves for supplying helium to a backside of a semiconductor substrate 162 supported thereon. Details of a substrate support including grooves for supplying helium to a backside of a substrate can be found in commonly-assigned U.S. Pat. No. 7,869,184 which is incorporated herein by reference in its entirety. The substrate support 160 can also include a lift pin assembly operable to lower a semiconductor substrate to the upper surface thereof and to raise a semiconductor substrate from the upper surface thereof. Details of a lift pin assembly for a substrate support can be found in commonly-assigned U.S. Pat. No. 8,840,754 which is incorporated herein by reference in its entirety.

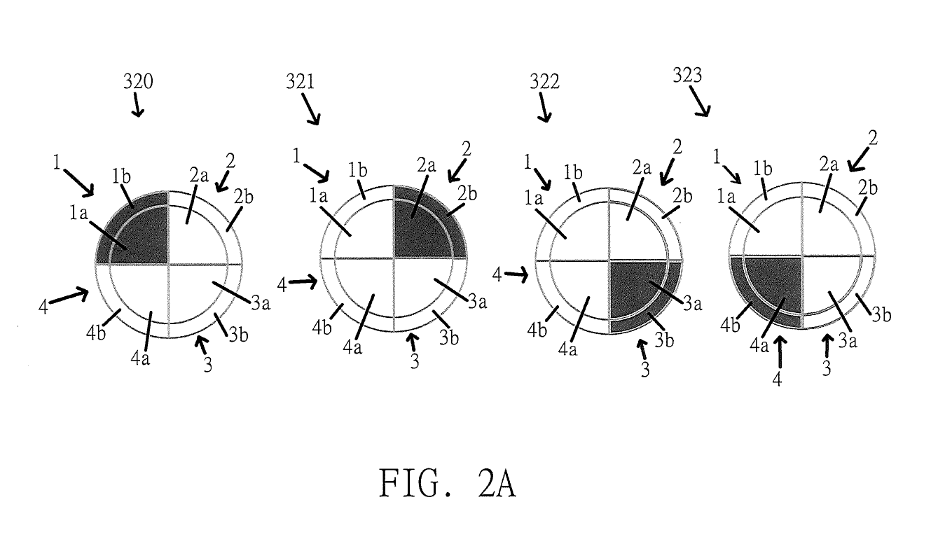

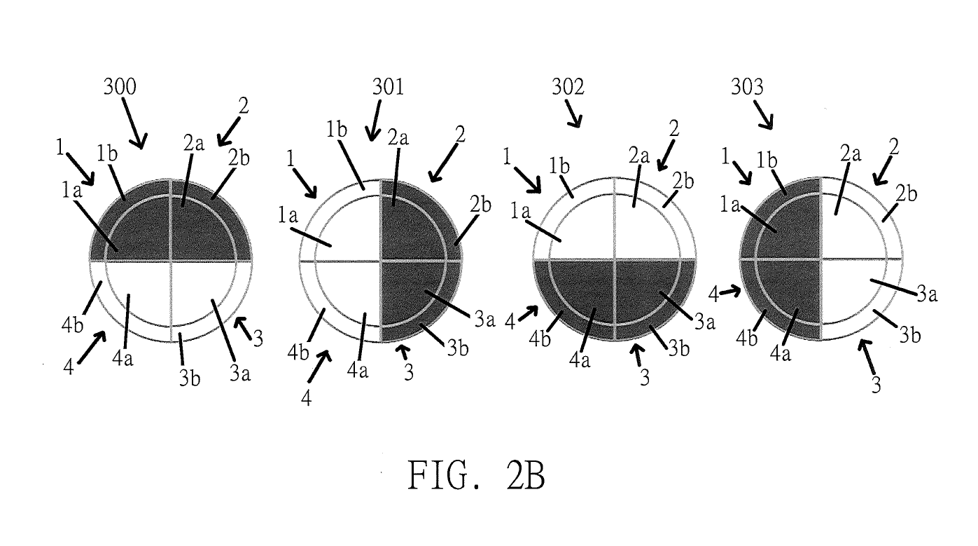

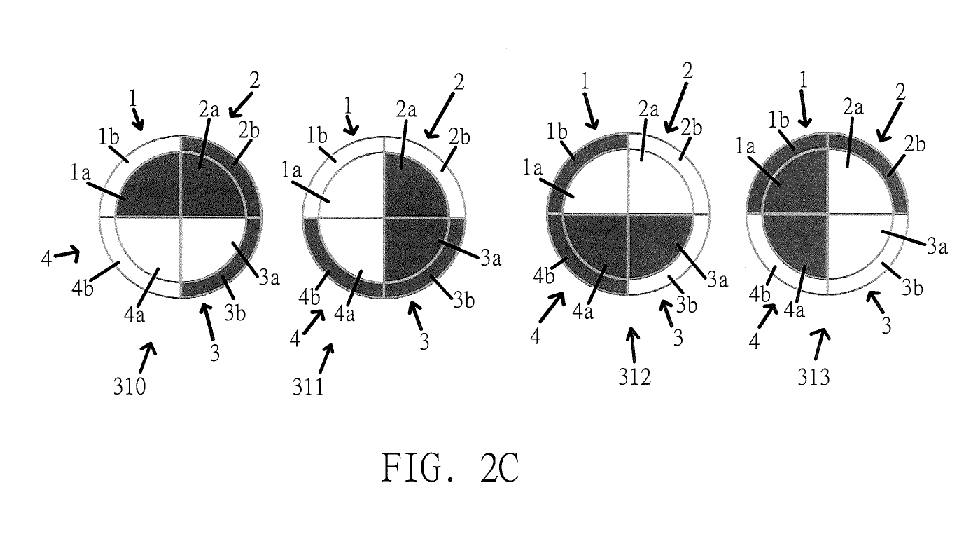

The top plate 111 can form a removable top wall of the vacuum chamber 12, such as a plasma etch vacuum chamber. As shown, the showerhead electrode 103 can be a showerhead electrode which includes an inner electrode member 105, and an optional outer electrode member 107. The inner electrode member 105 is typically made of single crystal silicon. If desired, the inner and outer electrodes 105, 107 can be made of a single piece of material such as CVD silicon carbide, single crystal silicon or other suitable material such as silicon based electrode material including aluminum oxide or the like. The showerhead electrode 103 includes a plasma exposed surface 118 which includes discrete sectors (see FIGS. 2A-2C) wherein gas can be independently supplied through outlets 113 of the discrete sectors by a gas supply delivery arrangement 500.

The gas supply delivery arrangement 500 is capable of providing controllable and tunable gas delivery to the vacuum chamber 12 through gas outlets 113 of the discrete sectors of the showerhead electrode 103 of the showerhead electrode assembly 100 so as to distribute gas to respective zones across the upper surface of a semiconductor substrate 162 underlying each discrete sector during plasma processing such as a plasma etching process. The gas supply delivery arrangement 500 can include a series of gas distribution and control components such as one or more mass flow controllers (MFC) in fluid communication with one or more respective gas supplies, one or more pressure transducers and/or regulators, heaters, one or more filters or purifiers, gas switching sections, gas splitters, and shutoff valves. The components used in a given gas supply delivery arrangement can vary depending upon the design and intended application of the gas supply delivery arrangement. In an embodiment of a semiconductor processing arrangement, over seventeen gases may be connected to the processing chamber via gas supply lines, gas distribution components, and mixing manifolds. These components are attached to a base plate forming a complete system known as a “gas panel” or “gas box.” An exemplary embodiment of a gas switching section can be found in commonly-assigned U.S. Pat. No. 8,772,171 which is incorporated herein by reference in its entirety.

In an embodiment, the gas delivery arrangement 500 includes respective gas lines operable to supply gas to each discrete sector of the showerhead electrode 103. Each gas line of the gas delivery arrangement 500 can be split such that gas can be independently delivered to two or more radial zones of each discrete sector of the showerhead electrode 103. The gas can be supplied to respective plenums of the showerhead electrode assembly 100 through the gas lines wherein each plenum corresponds to a discrete sector or a radial zone of each discrete sector of the showerhead electrode 103, such that gas can be distributed to respective zones across the upper surface of a semiconductor substrate 162 during plasma processing of the semiconductor substrate 162.

For example, as illustrated in FIG. 1, the gas delivery arrangement 500 includes a gas line 510 wherein gas supplied through the gas line 510 is delivered to the vacuum chamber 12 through gas outlets 113 of a first discrete sector 1 of the showerhead electrode 103. The gas line 510 is split into an inner gas line 511a and an outer gas line 511b. The inner gas line 511a is operable to supply gas to the vacuum chamber 12 through gas outlets 113 of an inner (radial) zone 1a of the first discrete sector 1 of the showerhead electrode 103, and the outer gas line 511b is operable to supply gas to the vacuum chamber 12 through gas outlets 113 of an outer (radial) zone 1b of the first discrete sector 1. The inner and outer gas lines 511a, 511b can each include a respective valve 501a, 501b such that the flow rate of gas delivered through the inner zone 1a and the outer zone 1b of the first discrete sector 1 across an upper surface of a semiconductor substrate 162 during processing in the vacuum chamber 12 can be independently controlled. A controller 505 is operable to control the valves 501a, 501b, and thereby the flow of gas through the respective inner gas line 511a and outer gas line 511b. In an embodiment, gas can be supplied by the inner and outer gas lines 511a, 511b of the gas delivery arrangement 500 to respective plenums 551a, 551b included in the showerhead electrode assembly 100 which correspond to the inner zone 1a and the outer zone 1b of the first discrete sector 1. In further embodiments, each discrete sector of the showerhead electrode 103 can be divided into more than two radial zones, such as three radial zones including an inner zone, a middle zone, and an outer zone, or alternatively, four or more zones including an inner zone, an outer zone, and two or more middle zones therebetween wherein respective valves can be used to control the flow rate through each zone of each discrete sector.

Exemplary dielectric materials that can be processed according to methods disclosed herein are, for example, doped silicon oxide, such as fluorinated silicon oxide; un-doped silicon oxide, such as silicon dioxide; spin-on glass; silicate glasses; doped or un-doped thermal silicon oxide; and doped or un-doped TEOS deposited silicon oxide. The dielectric material can be a low-k material having a selected k value. Such dielectric materials can overlie a conductive or semiconductive layer, such as polycrystalline silicon; metals, such as aluminum, copper, titanium, tungsten, molybdenum and their alloys; nitrides, such as titanium nitride; and metal silicides, such as titanium silicide, tungsten silicide and molybdenum silicide. For example, a multi-layer film stack (semiconductor substrate) including various layers which are processed during a multi-step etching process is disclosed in commonly-assigned U.S. Pat. No. 8,668,835, which is incorporated herein by reference in its entirety.

The number of gas sources included in the gas supply delivery arrangement 500 is not limited to any particular number of gas sources, but preferably includes at least two different gas sources. For example, the gas supply delivery arrangement 500 can include more than or less than eight gas sources, such as up to 17 gas sources, each in fluid communication with the gas splitter through the gas panel and a respective MFC. The different gases that can be provided by the respective gas sources include individual gases, such as O₂, Ar, H₂, Cl₂, N₂ and the like, as well as gaseous fluorocarbon and/or fluorohydrocarbon compounds, such as CF₄, CH₃F and the like. In an embodiment, the process chamber is a plasma processing etch chamber and the gas sources can supply Ar, O₂, N₂, Cl₂, CH₃, CF₄, C₄F₈ and CH₃F or CHF₃ (in any suitable order thereof). The particular gases supplied by the respective gas sources can be selected based on the desired process that is to be performed in the plasma processing chamber, which is determined by the particular material composition of an upper surface of the semiconductor substrate to be processed, e.g., a particular dry etching and/or material deposition process. The gas supply delivery arrangement 500 can provide broad versatility regarding the choice of gases that can be supplied for performing etching processes. The gas supply delivery arrangement 500 preferably also includes at least one tuning gas source to adjust the gas composition. The tuning gas can be, e.g., O₂, an inert gas, such as argon, or a reactive gas, such as a fluorocarbon or fluorohydrocarbon gas, e.g., C₄F₈.

Present embodiments disclosed herein include methods of uniformly processing an upper surface of a semiconductor substrate in a semiconductor substrate processing apparatus such as a plasma processing apparatus. The plasma processing apparatus includes a showerhead having gas outlets in discrete sectors of a process exposed surface thereof. The method can include processing the upper surface of the semiconductor substrate by flowing gas through a first discrete sector of the showerhead while preventing gas from flowing through an adjacent discrete sector of the showerhead, and processing the upper surface of the semiconductor substrate by flowing gas through a second discrete sector of the showerhead while preventing gas from flowing through an adjacent discrete sector of the showerhead. The flow of gas through the first discrete sector and the second discrete sector of the showerhead is time averaged such that the upper surface of the semiconductor substrate is uniformly processed.

In an embodiment, the showerhead can include a third discrete sector wherein the upper surface of the semiconductor substrate can be processed by flowing gas through the third discrete sector of the showerhead while preventing gas from flowing through an adjacent discrete sector of the showerhead wherein the flow of gas through the first, second, and third discrete sectors is time averaged such that the upper surface of the semiconductor substrate is uniformly processed. In a further embodiment, the showerhead can include a fourth discrete sector wherein the upper surface of the semiconductor substrate can be processed by flowing gas through the fourth discrete sector of the showerhead while preventing gas from flowing through an adjacent discrete sector of the showerhead wherein the flow of gas through the first, second, third, and fourth discrete sectors is time averaged such that the upper surface of the semiconductor substrate is uniformly processed.

For example, FIGS. 2A-2C show method steps of gas being supplied through four discrete sectors 1, 2, 3, and 4 of a process exposed surface of a showerhead. In an embodiment, each discrete sector 1, 2, 3, and 4 can include a respective inner and outer zone 1a, 1b, 2a, 2b, 3a, 3b, 4a, 4b. The flow rate of gas supplied through an inner and outer zone of a discrete sector can be independently controlled during processing. For example, if less gas is flowed to an inner zone, and more gas is flowed to an outer zone, the flow and pressure gradient can be reduced in the inner zone, and the extra process gas in the outer zone can displace byproducts in the outer zone. In a further embodiment, gas is intermittently blocked through either an inner zone or an outer zone of the first, second, third, or fourth discrete sectors 1, 2, 3, or 4 through which gas is flowed during processing.

FIG. 2A shows methods steps of gas being sequentially supplied through four discrete sectors 1, 2, 3, and 4 of a process exposed surface of a showerhead according to an embodiment as disclosed herein. The method includes, at step 320, flowing gas through the first discrete sector 1 while preventing gas from flowing through the second, third, and fourth discrete sectors 2, 3, and 4. At step 321 gas is flowed gas through the second discrete sector 2 while gas is prevented from flowing through the third, fourth, and first discrete sectors 3, 4, and 1. At step 322, gas is flowed through the third discrete sector 3 while gas is prevented from flowing through the fourth, first, and second discrete sectors 4, 1, and 2. At step 323 gas is flowed through the fourth discrete sector while gas is prevented from flowing through the first, second, and third discrete sectors. In an embodiment steps 320-323 can be repeated one or more times until a process recipe is completed.

In an embodiment as shown by the method steps of FIG. 2B, gas can be sequentially flowed through more than one discrete sector at a given time. For example, step 300 shows gas being flowed through the first and second discrete sectors 1, 2 while gas is prevented from flowing through the third and fourth discrete sectors 3, 4. At step 301, gas is flowed through the second and third discrete sectors 2, 3 while gas is prevented from flowing through the fourth and first discrete sectors 4, 1. At step 302, gas is flowed through the third and fourth discrete sectors 3, 4 while gas is prevented from flowing through the first and second discrete sectors 1, 2. At step 303, gas is flowed through the fourth and first discrete sectors 4, 1 while gas is prevented from flowing through the second and third discrete sectors 2, 3. In an embodiment, steps 300-303 may be repeated one or more times until a process recipe is completed.

In an embodiment as shown by the method steps of FIG. 2C, gas can be sequentially flowed through more than one discrete sector at a given time wherein gas is intermittently blocked through either an inner zone or an outer zone of the first, second, third, or fourth discrete sectors 1, 2, 3, or 4 through which gas is flowed during processing. For example, step 310 shows gas being flowed through the an inner zone 1a of the first discrete sector 1, the second discrete sector 2, and the outer zone 3b of the third discrete sector 3 while gas is prevented from flowing through the outer zone 1b of the first discrete sector 1, the inner zone 3a of the third discrete sector 3 and the fourth discrete sector 4. At step 311, gas is flowed through the an inner zone 2a of the second discrete sector 2, the third discrete sector 3, and the outer zone 4b of the fourth discrete sector 4 while gas is prevented from flowing through the outer zone 2b of the second discrete sector 2, the inner zone 4a of the fourth discrete sector 4 and the first discrete sector 1. At step 312, gas is flowed through the an inner zone 3a of the third discrete sector 3, the fourth discrete sector 4, and the outer zone 1b of the first discrete sector 1 while gas is prevented from flowing through the outer zone 3b of the third discrete sector 3, the inner zone la of the first discrete sector 1 and the second discrete sector 2. At step 313, gas is flowed through the an inner zone 4a of the fourth discrete sector 4, the first discrete sector 1, and the outer zone 2b of the second discrete sector 2 while gas is prevented from flowing through the outer zone 4b of the fourth discrete sector 4, the inner zone 2a of the second discrete sector 2 and the first discrete sector 1. In an embodiment steps 310-313 can be repeated one or more times until a process recipe is completed.

According to embodiments of methods disclosed herein, such as the embodiments shown in FIGS. 2A-2C, the same gas at the same flow rate can be intermittently supplied to the first, second, third, and fourth discrete sectors 1, 2, 3, and 4 at the same flow rate. In an alternative embodiment, the same gas at different flow rates is intermittently supplied to the first, second, third, and fourth discrete sectors 1, 2, 3, and 4 at varying flow rates. In a further embodiment, different gases can be supplied through one or more of the first, second, third, and fourth discrete sectors 1, 2, 3, and 4 at the same or varying flow rates.

In an embodiment, the method can include sequentially flowing gas through one or more of the discrete sectors while preventing the flow of gas through at least one other discrete sector wherein the gas flowed through the discrete sectors is time averaged such that the upper surface of the semiconductor substrate is uniformly processed. As explained above, each discrete sector can includes an inner zone and an outer zone, wherein embodiments of methods disclosed herein can include independently controlling the flow rate of gas through the inner zone and the outer zone of each discrete sector during processing. In an embodiment, the flow of gas can be intermittently blocked through either an inner zone or an outer zone of any discrete sector. In a preferred embodiment, the gas can be intermittently supplied through an inner zone of a first discrete sector and an outer zone of a second discrete sector which is adjacent to the first discrete sector wherein the outer zone of the first discrete sector and/or the inner zone of the second discrete sector may prevent gas from being supplied therethrough.

The gas can be intermittently flowed through discrete sectors for equal lengths of time, or alternatively the gas is intermittently flowed through discrete sectors for unequal lengths of time. Preferably, the gas is sequentially flowed through the discrete sectors wherein the sequence takes about 1 second. In alternate embodiments, the sequence may take less than 1 second or greater than 1 second. In an embodiment, the gas is sequentially flowed through different combinations of discrete sectors of the showerhead. For example, a combination of adjacent discrete sectors may have gas sequentially flowed therethrough, or alternatively two discrete sectors which are separated by one or more discrete sectors may have gas sequentially flowed therethrough.

The semiconductor substrate processing apparatus 100 and related gas supply delivery arrangement 500 which are operable to perform embodiments of methods as disclosed herein may be integrated with electronics for controlling their operation before, during, and after processing of a semiconductor wafer or substrate. The electronics may be referred to as the “controller,” which may control various components or subparts of the system or systems. For example, as illustrated in FIG. 1 the semiconductor substrate processing apparatus 100 and/or the gas supply delivery arrangement 500 includes the associated controller 505. The controller 505, depending on the processing requirements and/or the type of semiconductor substrate processing apparatus 100, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 505, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller 505 may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level (i.e. plasma processing apparatus 100) or as part of a remote computer) that combine to control a process on the chamber.

Without limitation, example semiconductor substrate processing apparatus 100 may include processing chambers including a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing apparatuses or systems that may be associated or used in the fabrication and/or manufacturing of semiconductor wafers.

As noted above, depending on the process step or steps to be performed by the semiconductor substrate processing apparatus 100, the controller 505 thereof might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory. Preferably, a non-transitory computer machine-readable medium includes program instructions for control of the semiconductor substrate processing apparatus 100.

Embodiments disclosed herein have been described with reference to preferred embodiments. However, it will be readily apparent to those skilled in the art that it is possible to embody the invention in specific forms other than as described above without departing from the spirit of the invention. The preferred embodiments are illustrative and should not be considered restrictive in any way. The scope of the invention is given by the appended claims, rather than the preceding description, and all variations and equivalents which fall within the range of the claims are intended to be embraced therein.

What is claimed is:

1. A method of uniformly processing an upper surface of a semiconductor substrate in a semiconductor substrate processing apparatus including a showerhead including gas outlets in discrete sectors of a process exposed surface thereof; the method comprising:
processing the upper surface of the semiconductor substrate by flowing gas through a first discrete sector of the showerhead while preventing gas from flowing through an adjacent discrete sector of the showerhead; and
processing the upper surface of the semiconductor substrate by flowing gas through a second discrete sector of the showerhead while preventing gas from flowing through an adjacent discrete sector of the showerhead;
wherein the flow of gas through the first discrete sector and the second discrete sector of the showerhead is time averaged such that the upper surface of the semiconductor substrate is uniformly processed.

2. The method of claim 1, further comprising processing the upper surface of the semiconductor substrate by flowing gas through a third discrete sector of the showerhead while preventing gas from flowing through an adjacent discrete sector of the showerhead wherein the flow of gas through the first, second, and third discrete sectors is time averaged such that the upper surface of the semiconductor substrate is uniformly processed.

3. The method of claim 2, further comprising processing the upper surface of the semiconductor substrate by flowing gas through a fourth discrete sector of the showerhead while preventing gas from flowing through an adjacent discrete sector of the showerhead wherein the flow of gas through the first, second, third, and fourth discrete sectors is time averaged such that the upper surface of the semiconductor substrate is uniformly processed.

4. The method of claim 3, wherein:
(a) each discrete sector has an inner zone and an outer zone, the method comprising independently controlling the flow rate of gas through the inner zone and the outer zone of each discrete sector during processing; or
(b) each discrete sector has an inner zone, an outer zone, and one or more middle zones therebetween, the method comprising independently controlling the flow rate of gas through the inner zone, the outer zone, and the one or more middle zones of each discrete sector during processing.

5. The method of claim 3, wherein each discrete sector has an inner zone and an outer zone, and the flow of gas is intermittently blocked through either an inner zone or an outer zone of the first, second, third, or fourth discrete sectors through which gas is flowed during processing.

6. The method of claim 3, wherein
(a) the same gas at the same flow rate is intermittently supplied to the first, second, third, and fourth discrete sectors at the same flow rate; or
(b) the same gas at different flow rates is intermittently supplied to the first, second, third, and fourth discrete sectors at varying flow rates.

7. The method of claim 3, comprising:
(a) flowing gas through the first and second discrete sectors while preventing gas from flowing through the third and fourth discrete sectors;
(b) flowing gas through the second and third discrete sectors while preventing gas from flowing through the fourth and first discrete sectors;
(c) flowing gas through the third and fourth discrete sectors while preventing gas from flowing through the first and second discrete sectors; and
(d) flowing gas through the fourth and first discrete sectors while preventing gas from flowing through the second and third discrete sectors.

8. The method of claim 7, and repeating steps (a)-(d).

9. The method of claim 3, comprising:
(a) flowing gas through the first discrete sector while preventing gas from flowing through the second, third, and fourth discrete sectors;
(b) flowing gas through the second discrete sector while preventing gas from flowing through the third, fourth, and first discrete sectors;
(c) flowing gas through the third discrete sector while preventing gas from flowing through the fourth, first, and second discrete sectors; and
(d) flowing gas through the fourth discrete sector while preventing gas from flowing through the first, second, and third discrete sectors.

10. The method of claim 9, and repeating steps (a)-(d).

11. The method of claim 1, wherein the showerhead is a showerhead electrode and the processing comprises plasma etching the upper surface of the semiconductor substrate.

12. A non-transitory computer machine-readable medium comprising program instructions for control of a plasma processing apparatus according to the method of claim 1.

13. A method of uniformly processing an upper surface of a semiconductor substrate in a semiconductor substrate processing apparatus including a showerhead including gas outlets in discrete sectors of a process exposed surface thereof; the method comprising:
sequentially flowing gas through one or more of the discrete sectors while preventing the flow of gas through at least one other discrete sector wherein the gas flowed through the discrete sectors is time averaged such that the upper surface of the semiconductor substrate is uniformly processed.

14. The method of claim 13, wherein the showerhead is a showerhead electrode and the processing comprises plasma etching the upper surface of the semiconductor substrate.

15. The method of claim 13, wherein:
(a) each discrete sector includes an inner zone and an outer zone, the method comprising independently controlling the flow rate of gas through the inner zone and the outer zone of each discrete sector during processing; or
(b) each discrete sector has an inner zone, an outer zone, and one or more middle zones therebetween, the method comprising independently controlling the flow rate of gas through the inner zone, the outer zone, and the one or more middle zones of each discrete sector during processing.

16. The method of claim 13, wherein each discrete sector includes an inner zone and an outer zone, the method comprising intermittently blocking the flow of gas through either an inner zone or an outer zone of any discrete sector.

17. The method of claim 13, wherein:
(a) the gas is intermittently flowed through discrete sectors for equal lengths of time; or
(b) the gas is intermittently flowed through discrete sectors for unequal lengths of time.

18. The method of claim 13, wherein
(a) the gas is intermittently supplied through an inner zone of a first discrete sector and an outer zone of a second discrete sector which is adjacent to the first discrete sector;
(b) the same gas at the same flow rate is intermittently supplied through the discrete sectors; and/or
(c) the gas is sequentially flowed through different combinations of discrete sectors of the showerhead.

19. The method of claim 13, wherein each discrete sector includes an inner zone and an outer zone, the method comprising intermittently blocking the flow of gas through an outer zone of a first discrete sector and an inner zone of a second discrete sector adjacent the first discrete sector.

20. A non-transitory computer machine-readable medium comprising program instructions for control of a plasma processing apparatus according to the method of claim 13.
